(19) United States
(12) Patent Application Publication
(10) Pub. No.: US 2025/0316467 A1
(43) Pub. Date: Oct. 9, 2025

(54) SYSTEM AND METHOD FOR DETECTING AND INHIBITING ARCING IN SEMICONDUCTOR PLASMA GENERATION SYSTEMS

(71) Applicant: Bird Technologies Group Inc., Solon, OH (US)

(72) Inventors: Amr Abdelmonem, Northbrook, IL (US); Martin Dummermuth, Chagrin Falls, OH (US); Michael Bonner, Gardiner, NY (US); Kathleen Wright, Newbury, OH (US)

(21) Appl. No.: 18/747,993

(22) Filed: Jun. 19, 2024

Related U.S. Application Data
(60) Provisional application No. 63/574,054, filed on Apr. 3, 2024.

(51) Int. Cl. H01J 37/32

(52) U.S. Cl. CPC H01J 37/32944; H01J 37/32174; H01J 37/3299

(57) ABSTRACT

A system and method for measuring and analyzing power flow parameters in RF-based excitation systems for semi-conductor plasma generators. A measuring probe is connected to an RF transmission line for receiving and measuring voltage and current signals from the transmission line. A high-speed sampling process converts the measured RF voltage and current signals into digital signals. The digital signals are then processed so as to reveal fundamental, intermodulation, triple beat, and harmonic amplitude and phase information corresponding to the original RF signals. The measurement system may also inhibit arcing by detecting when the amplitude of the intermodulation or triple beat signal exceeds a predetermined threshold, and indicating an alarm and/or reducing the power of the plasma generator when the predetermined threshold is exceeded.

### CROSS-REFERENCE TO RELATED APPLICATION

This application claims the priority benefit of U.S. Provisional Patent Application No. 63/574,054, which was filed on Apr. 3, 2024, and is herein incorporated by reference in its entirety.

### FIELD OF THE INVENTION

The present invention relates generally to the measurement of power flow in RF transmission systems, and more particularly relates to systems and methods for measuring fundamental, intermodulation (IM), triple beat (TB) and harmonic amplitude and phase relationships of voltage and current signals in RF-based excitation systems for semiconductor plasma generators and use the measurements to inhibit arcing conditions.

### BACKGROUND OF THE INVENTION

RF plasma reactors of the type employed in processing semiconductor wafers require a large amount of RF power. Basically, the technique involves the ignition and maintenance of a processing plasma through the application of electric power to the plasma. The plasma interacts with gases introduced and with the target and wafer surfaces involved to affect the desired processing results.

Due to the increasing complexity of semiconductor devices, tighter and tighter control over the manufacturing process has been required. In order to achieve tighter process control in modern plasma processing, it is desirable to obtain more information about the associated RF voltage and current signals under actual processing conditions. This usually has been done by available V-I probes inserted in the power transmission path to measure the fundamental, intermodulation, triple beat, and harmonic signal power being directed to the plasma generation system.

### SUMMARY OF THE INVENTION

A measuring probe for measuring power flow in an RF power transmission system, including a voltage sensor and a current sensor connected to a measuring receiver for receiving and measuring RF voltage and current signals. RF voltage and current signals are converted into digital representations of the RF waveforms, either directly, or by sampling-based frequency converters that bring the RF voltage and current signals to a fixed intermediate frequency (IF) before digital conversion. The digital representations of the RF signals contain fundamental, intermodulation, triple beat and harmonic amplitude and phase information relating to the original RF signals. Digital signal processing circuitry manages data capture, mathematical transforms, signal filters, scaling, and creation of mathematically alterable analog outputs for external process control. Also, the circuitry extracts information about the fundamental, intermodulation, triple beat and harmonic amplitude and phase components of each of the original RF signals. The increase of the magnitude of those signals can be used to trigger an alarm to reduce the signal generator RF power to prevent an arcing in the chamber. A universal serial bus (USB) and/or Ethernet connection is provided for connecting the measuring receiver to an external computer for additional numerical and graphical analysis.

Also disclosed is a method for measuring and analyzing power flow parameters in an RF transmission system wherein a plurality of measuring probes are inserted in the power transmission path to determine impedance match, insertion loss and power flow. The networked probes may provide two-port measurements, and may be used to determine input impedance, output impedance, insertion loss, internal dissipation, power flow efficiency, scattering, and the effect of plasma non-linearity on the RF signal. In one exemplary embodiment of the present invention, a single measuring receiver is employed to retrieve data from several probes, wherein the data from the several probes is fed to an external computer for post processing. In another exemplary embodiment, multiple measuring receivers are connected to each probe individually, thereby allowing for “real time” processing of system data.

In accordance to one aspect of the present invention, a system for analyzing power flow in a radio frequency (RF) power transmission line, comprising: a measuring probe having a voltage sensor and a current sensor for sensing RF voltage and current signals from the transmission line, the RF voltage and current signals having waveforms; a measuring receiver connected to the voltage and current sensors for receiving the RF signals; a sampler for directly converting the RF signals to digital signals, the digital signals comprising amplitude and phase information representing a fundamental frequency of the RF signals and a predetermined number of intermodulation (IM), triple beat (TB), and harmonic frequencies.

In another aspect of the invention, the system further includes a digital signal processor for characterizing the amplitude and phase information so as to analyze power flow parameters and to reveal amplitude and phase angle relationships between the fundamental, intermodulation, triple beat, and harmonic frequencies; wherein the digital signal processor reconstructs the RF voltage and current waveforms by recombining the harmonic frequencies in the proper phase relationships using the information about phase angle relationships between the fundamental, intermodulation, triple beat, and harmonic frequencies.

In another aspect of the invention, the system generates an alarm when the amplitude of at least one of the intermodulation or triple beat frequencies exceed a predetermined threshold.

In another aspect of the invention, the predetermined threshold is: about 3 dB, about double a nominal IM value for a power output of a power source for conditions of a chamber, about double a nominal TB value for the power output of the power source for conditions of the chamber, and/or a value that inhibits an arcing condition within the chamber.

In another aspect of the invention, the predetermined threshold is a predetermined IM threshold, a predetermined delivered power threshold, and/or a predetermined reflected power threshold.

In another aspect of the invention, the system further includes a digital-to-analog converter for reconstructing the RF signals.

In another aspect of the invention, the probe and the transmission line comprise memory for storing calibration data from the probe and the transmission line, respectively.

In another aspect of the invention, the system takes at least three uncorrelated individual measurements of the RF signals using cross-correlation for reduction of uncertainty, wherein the individual measurements of the RF signals are averaged together, thereby producing an aggregate average measurement of the RF signals and providing to a user a more accurate representation of the fundamental frequency of the RF signals and the predetermined number of intermodulation or triple beat and harmonic frequencies.

In another aspect of the invention, the measuring receiver comprises a digital interface for receiving the calibration data from the probe and the transmission line. In another aspect of the invention, the system also includes a computer connected to the digital signal processor for additional numerical and graphical processing of the digital signals. In another aspect of the invention, the system also includes an equalizer to compensate for fluctuations in the RF voltage and current signals.

In another aspect of the invention, the sampler includes a band-pass sampling analog-to-digital converter for sampling the RF signals.

In another aspect of the invention, the sampler comprises a Nyquist sampling rate analog-to-digital converter for the sampling RF signals.

In another aspect of the invention, the sampler comprises a combination of a Nyquist sampling rate analog-to-digital converter and a band-pass sampling analog-to-digital converter for sampling the RF signals.

In another aspect of the invention, the predetermined number of intermodulation, triple beat, and harmonics includes up to about fifteen orders of the fundamental frequency.

In another aspect of the invention, the power flow parameters comprise input impedance, insertion loss, internal dissipation, plasma non-linearity, power flow efficiency, scattering, and combinations thereof.

According to yet another aspect of the invention, a method of analyzing power flow in an RF transmission line, comprising the steps of: connecting at least one measuring probe to the RF transmission line; receiving RF voltage and current signals from the RF transmission line via the at least one measuring probe, the RF voltage and current signals having waveforms; converting the RF signals to corresponding digital signals, the digital signals comprising amplitude and phase information representing a fundamental frequency of the RF signals and a predetermined number of intermodulation, triple beat, and harmonic frequencies.

In another aspect of the invention, the predetermined number of intermodulation, triple beat, and harmonics includes up to about fifteen orders of the fundamental frequency.

In another aspect of the invention, the method further includes, processing the digital signals so as to analyze power flow parameters and to reveal amplitude and phase angle relationships between the fundamental, intermodulation, triple beat, and harmonic frequencies; wherein the information about phase angle relationships between the fundamental, intermodulation, triple beat, and harmonic frequencies permits the recombining of the harmonic frequencies in the proper phase relationships so as to reconstruct the RF voltage and current waveforms.

In another aspect of the invention, the power flow parameters comprise input impedance, insertion loss, internal dissipation, plasma non-linearity, power flow efficiency, scattering, and combinations thereof.

In another aspect of the invention, the method further comprises generating an alarm when the amplitude of at least one of the intermodulation or triple beat frequencies exceed a predetermined threshold.

In another aspect of the invention, the predetermined threshold is: about 3 dB, about double a nominal IM value for a power output of a power source for conditions of a chamber, about double a nominal TB value for the power output of the power source for conditions of the chamber, and/or a value that inhibits an arcing condition within the chamber.

In another aspect of the invention, the predetermined threshold is a predetermined IM threshold, a predetermined delivered power threshold, and/or a predetermined reflected power threshold.

In another aspect of the invention, the method further includes the steps of: converting the digital signals to analog signals so as to reconstruct the RF signals; and transmitting the digital signals to an external computer for additional numerical and graphical processing.

In another aspect of the invention, the method further includes the steps of storing calibration data from the at least one probe and the transmission line and downloading the calibration data to a measuring receiver.

In another aspect of the invention, the method further includes the steps of interchanging the at least one probe and/or the transmission line, and downloading updated calibration data from the interchanged probe and/or transmission line to the measuring receiver.

In another aspect of the invention, the method further comprises taking at least three uncorrelated individual measurements of the RF signals using cross-correlation for reduction of uncertainty, wherein the individual measurements of the RF signals are averaged together, thereby producing an aggregate average measurement of the RF signals and providing to a user a more accurate representation of the fundamental frequency of the RF signals and the predetermined number of intermodulation or triple beat and harmonic frequencies. In another aspect of the invention, the method further includes the step of displaying results of the processing steps in a user controlled format.

In another aspect of the invention, the method further includes the steps of: connecting an RF power source and a tool chuck to the RF transmission line; connecting a matching network to the RF transmission line between the power source and the tool chuck; connecting at least one of the probes between the power source and the matching network, and connecting another one of the probes between the matching network and the tool chuck.

In another aspect of the invention, the sampling is performed by taking at least two samples for each cycle at a highest the predetermined harmonics of the fundamental frequency.

According to yet another aspect of the invention, a system for analyzing power flow in a radio frequency (RF) power transmission line, comprising: a measuring probe for sensing RF voltage and current signals on the transmission line, the signals having a waveform; a processor and a memory communicatively connected to the processor, the memory storing instructions that, when executed by the processor, cause the processor to: measure on the transmission line a fundamental frequency RF signal power and an intermodulation (IM) power for a predetermined number of cycles of the fundamental frequency at a steady state using the measuring probe; calculate baseline measurements using the measurements of the fundamental frequency RF signal power and the IM power, the baseline measurements comprising one or more of an average and a variation in the IM power with respect to the fundamental frequency power; establish predetermined thresholds for the fundamental frequency power and the IM power based on the calculated baseline measurements; obtain measurements of the fundamental frequency power and the IM power on the transmission line, and compare the measured fundamental frequency power and the IM power to the predetermined threshold for the fundamental frequency power and the predetermined threshold for the IM power to detect a presence of a potential arcing condition; and set an alarm and/or mitigate the potential arcing condition, when the potential arcing condition is detected.

In another aspect of the invention, the memory storing instructions that, when executed by the processor, cause the processor to: set an arcing potential alarm and/or reduce power of an RF generator, when the IM power measurement exceeds the predetermined IM power threshold, and a delivered power measurement of the measured fundamental frequency power does not exceed a predetermined delivered power threshold of the predetermined fundamental frequency power threshold.

In another aspect of the invention, the memory storing instructions that, when executed by the processor, cause the processor to: set an excess power delivery alarm, when: the IM power measurement exceeds the predetermined IM power threshold; a delivered power measurement of the measured fundamental frequency power exceeds a predetermined delivered power threshold of the predetermined fundamental frequency power threshold; and a delivered power measurement of the measured fundamental frequency power exceeds a predetermined delivered power threshold of the predetermined fundamental frequency power threshold.

In another aspect of the invention, the memory storing instructions that, when executed by the processor, cause the processor to: set a matching network adjustment alarm, when: the IM power measurement exceeds the predetermined IM power threshold; a delivered power measurement of the measured fundamental frequency power exceeds a predetermined delivered power threshold of the predetermined fundamental frequency power threshold; and a reflected power measurement of the measured fundamental frequency power exceeds a predetermined reflected power threshold of the predetermined fundamental frequency power threshold.

In another aspect of the invention, wherein IM power is one or more of IM3, IM5, IM7, IM9, and/or TB.

In another aspect of the invention, the predetermined number of cycles may be a value between 1 and 10.

In another aspect of the invention, the predetermined fundamental frequency power threshold is a multiple between 2 and 5 of the average fundamental frequency power at steady state, and/or the IM power threshold is a multiple between 2 and 5 of the average value and/or standard deviation in the IM power with respect to the fundamental frequency power at steady state.

According to yet another aspect of the invention, a method for analyzing power flow in a radio frequency (RF) power transmission line, comprising: providing a measuring probe for sensing RF voltage and current signals on the transmission line, the signals having a waveform; measuring on the transmission line a fundamental frequency RF signal power and an intermodulation (IM) power for a predetermined number of cycles of the fundamental frequency at a steady state using the measuring probe; calculating baseline measurements using the measurements of the fundamental frequency RF signal power and the IM power, the baseline measurements comprising one or more of an average and a variation in the IM power with respect to the fundamental frequency power; establishing predetermined thresholds for the fundamental frequency power and the IM power based on the calculated baseline measurements; obtaining measurements of the fundamental frequency power and the IM power on the transmission line, and comparing the measured fundamental frequency power and the IM power to the predetermined threshold for the fundamental frequency power and the predetermined threshold for the IM power to detect a presence of a potential arcing condition; and setting an alarm and/or mitigate the potential arcing condition, when the potential arcing condition is detected.

In another aspect of the invention, the method further comprising, setting an arcing potential alarm and/or reduce power of an RF generator, when the IM power measurement exceeds the predetermined IM power threshold, and a delivered power measurement of the measured fundamental frequency power does not exceed a predetermined delivered power threshold of the predetermined fundamental frequency power threshold.

In another aspect of the invention, the method further comprising, setting an excess power delivery alarm, when: the IM power measurement exceeds the predetermined IM power threshold; a delivered power measurement of the measured fundamental frequency power exceeds a predetermined delivered power threshold of the predetermined fundamental frequency power threshold; and a delivered power measurement of the measured fundamental frequency power exceeds a predetermined delivered power threshold of the predetermined fundamental frequency power threshold.

In another aspect of the invention, the method further comprising, setting a matching network adjustment alarm, when: the IM power measurement exceeds the predetermined IM power threshold; a delivered power measurement of the measured fundamental frequency power exceeds a predetermined delivered power threshold of the predetermined fundamental frequency power threshold; and a reflected power measurement of the measured fundamental frequency power exceeds a predetermined reflected power threshold of the predetermined fundamental frequency power threshold.

In another aspect of the invention, IM power is one or more of IM3, IM5, IM7, IM9, and/or TB.

In another aspect of the invention, the predetermined number of cycles may be a value between 1 and 10.

In another aspect of the invention, the predetermined fundamental frequency power threshold is a multiple between 2 and 5 of the average fundamental frequency power at steady state, and/or the IM power threshold is a multiple between 2 and 5 of the average value and/or standard deviation in the IM power with respect to the fundamental frequency power at steady state.

According to yet another aspect of the invention, a system for analyzing power flow in a radio frequency (RF) power transmission line, comprising: a measuring probe for sensing RF voltage and current signals on the transmission line, the signals having a waveform; a processor and a memory communicatively connected to the processor, the memory storing instructions that, when executed by the processor, cause the processor to: measure on the transmission line a fundamental frequency RF signal power amplitude and an intermodulation (IM) power amplitude for a predetermined number of cycles of the fundamental frequency at a steady state using the measuring probe; calculate baseline measurements using the measurements of the fundamental frequency RF signal power amplitude and the IM power amplitude, the baseline measurements comprising one or more of an average and a variation in the IM power amplitude with respect to the fundamental frequency power amplitude; establish predetermined thresholds for the fundamental frequency power amplitude and the IM power amplitude based on the calculated baseline measurements; obtain measurements of the fundamental frequency power amplitude and the IM power amplitude on the transmission line, and compare the measured fundamental frequency power amplitude and the IM power amplitude to the predetermined threshold for the fundamental frequency power amplitude and the predetermined threshold for the IM power amplitude to detect a presence of a potential arcing condition; and set an alarm and/or mitigate the potential arcing condition, when the potential arcing condition is detected.

In another aspect of the invention, the memory storing instructions that, when executed by the processor, cause the processor to: set an arcing potential alarm and/or reduce power of an RF generator, when the IM power measurement exceeds the predetermined IM power amplitude threshold, and a delivered power measurement of the measured fundamental frequency power amplitude does not exceed a predetermined delivered power amplitude threshold of the predetermined fundamental frequency power amplitude threshold.

In another aspect of the invention, the memory storing instructions that, when executed by the processor, cause the processor to: set an excess power delivery alarm, when: the IM power amplitude measurement exceeds the predetermined IM power amplitude threshold; a delivered power amplitude measurement of the measured fundamental frequency power amplitude exceeds a predetermined delivered power amplitude threshold of the predetermined fundamental frequency power amplitude threshold; and a delivered power measurement of the measured fundamental frequency power amplitude exceeds a predetermined delivered power amplitude threshold of the predetermined fundamental frequency power amplitude threshold.

In another aspect of the invention, the memory storing instructions that, when executed by the processor, cause the processor to: set a matching network adjustment alarm, when: the IM power amplitude measurement exceeds the predetermined IM power amplitude threshold; a delivered power amplitude measurement of the measured fundamental frequency power amplitude exceeds a predetermined delivered power amplitude threshold of the predetermined fundamental frequency power amplitude threshold; and a reflected power measurement of the measured fundamental frequency power amplitude exceeds a predetermined reflected power amplitude threshold of the predetermined fundamental frequency power amplitude threshold.

In another aspect of the invention, wherein IM power is one or more of IM3, IM5, IM7, IM9, and/or TB.

In another aspect of the invention, the predetermined number of cycles may be a value between 1 and 10.

In another aspect of the invention, the predetermined fundamental frequency power amplitude threshold is a multiple between 2 and 5 of the average fundamental frequency power amplitude at steady state, and/or the IM power amplitude threshold is a multiple between 2 and 5 of the average value and/or standard deviation in the IM power amplitude with respect to the fundamental frequency power amplitude at steady state.

According to yet another aspect of the invention, a method for analyzing power flow in a radio frequency (RF) power transmission line, comprising: providing a measuring probe for sensing RF voltage and current signals on the transmission line, the signals having a waveform; measuring on the transmission line a fundamental frequency RF signal power amplitude and an intermodulation (IM) power amplitude for a predetermined number of cycles of the fundamental frequency at a steady state using the measuring probe; calculating baseline measurements using the measurements of the fundamental frequency RF signal power amplitude and the IM power amplitude, the baseline measurements comprising one or more of an average and a variation in the IM power amplitude with respect to the fundamental frequency power amplitude; establishing predetermined thresholds for the fundamental frequency power amplitude and the IM power amplitude based on the calculated baseline measurements; obtaining measurements of the fundamental frequency power amplitude and the IM power amplitude on the transmission line, and comparing the measured fundamental frequency power amplitude and the IM power amplitude to the predetermined threshold for the fundamental frequency power amplitude and the predetermined threshold for the IM power amplitude to detect a presence of a potential arcing condition; and setting an alarm and/or mitigate the potential arcing condition, when the potential arcing condition is detected.

In another aspect of the invention, the method further comprising, setting an arcing potential alarm and/or reduce power of an RF generator, when the IM power amplitude measurement exceeds the predetermined IM power amplitude threshold, and a delivered power amplitude measurement of the measured fundamental frequency power amplitude does not exceed a predetermined delivered power amplitude threshold of the predetermined fundamental frequency power amplitude threshold.

In another aspect of the invention, the method further comprising, setting an excess power delivery alarm, when: the IM power amplitude measurement exceeds the predetermined IM power amplitude threshold; a delivered power amplitude measurement of the measured fundamental frequency power amplitude exceeds a predetermined delivered power amplitude threshold of the predetermined fundamental frequency power amplitude threshold; and a delivered power measurement of the measured fundamental frequency power amplitude exceeds a predetermined delivered power amplitude threshold of the predetermined fundamental frequency power amplitude threshold.

In another aspect of the invention, the method further comprising, setting a matching network adjustment alarm, when: the IM power amplitude measurement exceeds the predetermined IM power amplitude threshold; a delivered power amplitude measurement of the measured fundamental frequency power amplitude exceeds a predetermined delivered power amplitude threshold of the predetermined fundamental frequency power amplitude threshold; and a reflected power amplitude measurement of the measured fundamental frequency power amplitude exceeds a predetermined reflected power amplitude threshold of the predetermined fundamental frequency power amplitude threshold.

In another aspect of the invention, IM power is one or more of IM3, IM5, IM7, IM9, and/or TB.

In another aspect of the invention, the predetermined number of cycles may be a value between 1 and 10.

In another aspect of the invention, the predetermined fundamental frequency power amplitude threshold is a multiple between 2 and 5 of the average fundamental frequency power amplitude at steady state, and/or the IM power amplitude threshold is a multiple between 2 and 5 of the average value and/or standard deviation in the IM power amplitude with respect to the fundamental frequency power amplitude at steady state.

The above and still further objects, features and advantages of the present invention will become apparent upon consideration of the following detailed description of exemplary embodiments thereof in conjunction with the accompanying drawings and appended claims.

### BRIEF DESCRIPTION OF DRAWINGS

FIG. 1A is a general block diagram illustrating the operational concept of an embodiment of the invention;

FIG. 1B is a block diagram illustrating the controller of FIG. 1A in accordance with an embodiment of the present invention;

FIG. 2 is a schematic drawing of an exemplary probe assembly in accordance with an embodiment of the present invention;

FIGS. 3A, 3B are schematic block diagrams illustrating a processing circuit for carrying out a process of the present invention;

FIGS. 4A, 4B, and 4C are graphs illustrating exemplary voltage, current, and power waveforms, respectively, generated in accordance with an embodiment of the present invention;

FIG. 5 is a graph illustrating power waveform versus frequency, generated in accordance with an embodiment of the present invention;

FIGS. 6A and 6B are illustrations of the intermodulation signals and triple beat signals relative to fundamental frequencies, in accordance with an embodiment of the present invention;

FIG. 7 is an illustration of the increase in the amplitude of the intermodulation and triple beat signals as the plasma gets closer to arcing condition and becomes more nonlinear, in accordance with an embodiment of the present invention;

FIG. 8 is an illustration of a flow chart of IM detection and arcing prevention in accordance with an embodiment of the present invention;

FIG. 9 is a general block diagram illustrating the concept of the IM detection controlling the RF generator in accordance with an embodiment of the present invention; and

FIG. 10 is a schematic block diagram illustrating a multiple probe networking arrangement for carrying out a process of the present invention.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF INVENTION

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

A “processor”, as used herein, processes signals and performs general computing and arithmetic functions. Signals processed by the processor can include digital signals, data signals, computer instructions, processor instructions, messages, a bit, a bit stream, or other means that can be received, transmitted and/or detected. Generally, the processor can be a variety of various processors including multiple single and multicore processors and co-processors and other multiple single and multicore processor and co-processor architectures, including, but not limited to, a microcontroller containing both a processor and memory, programmable logic array (PLA), application specific integrated circuit (ASIC), or any type of device suitable for processing signals, performing general computing, and/or arithmetic functions. The processor can include various modules to execute various functions.

A “memory”, as used herein can include volatile memory and/or nonvolatile memory. Non-volatile memory can include, for example, ROM (read only memory), PROM (programmable read only memory), EPROM (erasable PROM), and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDRSDRAM), and direct RAM bus RAM (DRRAM). The memory can also include a disk. The memory can store an operating system that controls or allocates resources of a computing device. The memory can also store data for use by the processor.

A “module”, as used herein, includes, but is not limited to, hardware, firmware, software in execution on a machine, and/or combinations of each to perform a function(s) or an action(s), and/or to cause a function or action from another module, method, and/or system. A module can include a software controlled microprocessor, a discrete logic circuit, an analog circuit, a digital circuit, a programmed logic device, a memory device containing executing instructions, and so on.

A “disk”, as used herein can be, for example, a magnetic disk drive, a solid state disk drive, a floppy disk drive, a tape drive, a Zip drive, a flash memory card, and/or a memory stick. Furthermore, the disk can be a CD-ROM (compact disk ROM), a CD recordable drive (CD-R drive), a CD rewritable drive (CD-RW drive), and/or a digital video ROM drive (DVD ROM). The disk can store an operating system and/or program that controls or allocates resources of a computing device.

Some portions of the detailed description that follows are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps (instructions) leading to a desired result. The steps are those requiring physical manipulations of physical quantities. Usually, though not necessarily, these quantities take the form of electrical, magnetic or optical non-transitory signals capable of being stored, transferred, combined, compared and otherwise manipulated. It is convenient at times, principally for reasons of common usage, to refer to these signals as bits, values, elements, symbols, characters, terms, numbers, or the like. Furthermore, it is also convenient at times, to refer to certain arrangements of steps requiring physical manipulations or transformation of physical quantities or representations of physical quantities as modules or code devices, without loss of generality.

However, all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or “determining” or the like, refer to the action and processes of a computer system, or similar electronic computing device (such as a specific computing machine), that manipulates and transforms data represented as physical (electronic) quantities within the computer system memories or registers or other such information storage, transmission or display devices.

Certain aspects of the embodiments described herein include process steps and instructions described herein in the form of an algorithm. It should be noted that the process steps and instructions of the embodiments could be embodied in software, firmware or hardware, and when embodied in software, could be downloaded to reside on and be operated from different platforms used by a variety of operating systems. The embodiments can also be in a computer program product which can be executed on a computing system.

The embodiments also relates to an apparatus for performing the operations herein. This apparatus can be specially constructed for the purposes, e.g., a specific computer, or it can comprise a general-purpose computer selectively activated or reconfigured by a computer program stored in the computer. Such a computer program can be stored in a non-transitory computer readable storage medium, such as, but is not limited to, any type of disk including floppy disks, optical disks, CD-ROMs, magnetic-optical disks, read-only memories (ROMs), random access memories (RAMs), EPROMS, EEPROMs, magnetic or optical cards, ASICs, or any type of media suitable for storing electronic instructions, and each electrically connected to a computer system bus. Furthermore, the computers referred to in the specification can include a single processor or can be architectures employing multiple processor designs for increased computing capability.

The algorithms and displays presented herein are not inherently related to any particular computer or other apparatus. Various general-purpose systems can also be used with programs in accordance with the teachings herein, or it can prove convenient to construct more specialized apparatus to perform the method steps. The structure for a variety of these systems will appear from the description below. In addition, the embodiments are not described with reference to any particular programming language. It will be appreciated that a variety of programming languages can be used to implement the teachings of the embodiments as described herein, and any references below to specific languages are provided for disclosure of enablement and best mode of the embodiments.

In addition, the language used in the specification has been principally selected for readability and instructional purposes, and may not have been selected to delineate or circumscribe the inventive subject matter. Accordingly, the disclosure of the embodiments is intended to be illustrative, but not limiting, of the scope of the embodiments, which is set forth in the claims.

With reference to the drawings which illustrate the basic concepts of the present invention, which builds upon U.S. Pat. No. 7,885,774, which is incorporated by reference herein in its entirety.

Due to the increasing complexity of semiconductor devices, tighter and tighter control over the manufacturing process has been required. In order to achieve tighter process control in modern plasma processing, it is desirable to obtain more information about the associated RF voltage and current signals under actual processing conditions. This usually has been done by available V-I probes inserted in the power transmission path to measure the fundamental, intermodulation, triple beat and harmonic signal power being directed to the plasma generation system.

Those skilled in the art have recognized that the fundamental, intermodulation, triple beat and harmonic amplitude and phase angle relationships of the RF voltage and current signals account for much of the variation in process performance during semiconductor wafer manufacture. Due to non-linearity of the processing plasma, intermodulation, triple beat and harmonics of the fundamental RF excitation frequency will be induced, even if the load appears to be matched at its fundamental frequency. As a result, the overall power delivered to the processing plasma includes the sum of the power levels of the fundamental, intermodulation, triple beat and harmonic frequencies. Known plasma processing tools routinely employ two or more RF signal frequencies to enhance process performance yields. However, the introduction of two or more excitation frequencies into the plasma generation system tends to increase process uncertainty due to the introduction of intermodulation frequency as well as triple beat components into the total power flow. As the plasma gets closer to arcing conditions its nonlinearity increases causing an increase in the amplitude of the intermodulation or triple beat signals.

Prior art attempts have been made to characterize power flow in plasma processing, such as those disclosed in U.S. Pat. Nos. 5,523,955 and 5,273,610. For example, U.S. Pat. No. 5,523,955 discloses a measuring probe inserted in the power transmission path for sensing RF signals. The sensed signals are then used to indirectly derive AC signals for calculating phase angle information relating to the original sensed signals. However, until the present invention, the techniques required to directly measure the relative phase angle information of the fundamental, intermodulation, triple beat and harmonic frequency content of the RF voltage and current signals in an accurate and stable fashion have not been readily available to those skilled in the art.

Therefore, there remains a strong need to provide a system and method for measuring and analyzing the critical amplitude and phase angle relationships between the fundamental signal frequencies, intermodulation, triple beat and harmonics of the fundamental frequencies. Information characterizing the frequency content of the RF excitation signals can then be monitored to regulate and control power flow to the processing chamber in order to improve manufacturing yields and make plasma processing more controlled and repeatable. The nonlinearity of the plasma, such as due to the use of multiple frequencies to generate the plasma, can cause significant impact on the intermodulation and triple beat signals, that will cause change in their amplitude as the plasma gets closer to arcing condition. This increase in amplitude of the intermodulation and triple beat can be monitored and used to prevent the arcing conditions from being reached by alerting the RF signal generator to reduce its power. In some embodiments, the measurement system 1 that measures the intermodulation and triple beat is in communication with the RF signal generator and can produce an alarm and/or reduce the power output of the RF signal generator, when the amplitude of the intermodulation and/or triple beat exceeds a predetermined threshold.

Due to non-linearity of the processing plasma and the use of multiple frequencies, intermodulation and triple beat signals will be generated. The increase of the amplitude of the intermodulation or triple beat signal as the plasma becomes more nonlinear as it approaches the arcing condition can be used to trigger an alarm when it exceeds a certain level to prevent (inhibit) the conditions that lead to an arcing from happening.

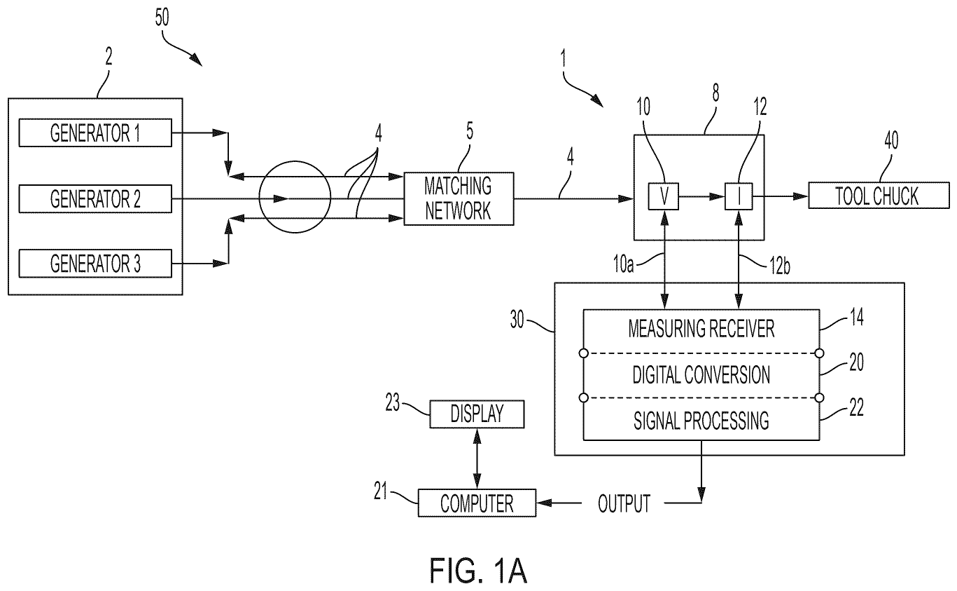

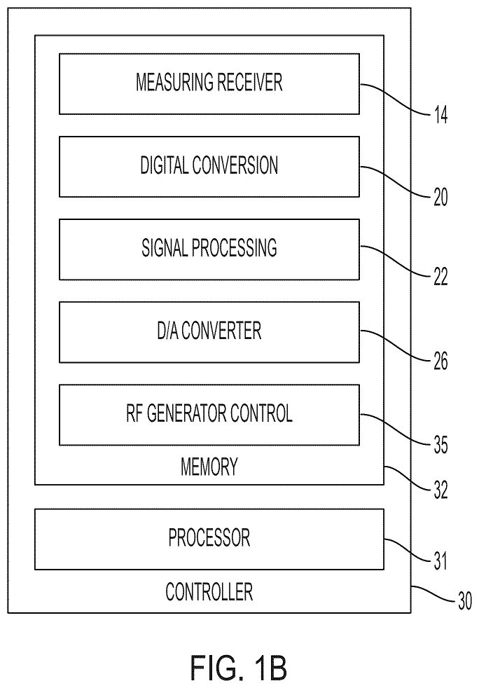

FIG. 1A is a general block diagram illustrating a system 1 for measuring the fundamental, intermodulation, triple beat, and harmonic amplitude and phase relationships in an RF-based excitation system. Stated alternatively, the measurement system 1, may measure the amplitude and phase relationships between the fundamental, intermodulation, triple beat, and harmonics in an RF based excitation system.

The RF based excitation system 50 may have one or more alternating power sources 2 generate alternating voltage and current signals which are transmitted via RF transmission lines 4 through a matching network 5 to a tool chuck 40, which may for example be a semiconductor plasma reactor. For purposes of the present disclosure, the term ‘transmission line’ is meant to encompass all known or later developed means for transmitting electrical signals including, but not limited to coaxial cable, waveguide, microstrip, twisted-pair, copper wire, and the like.

The matching network 5 converts the complex impedance of the plasma to match the characteristic load impedance for the generator at its fundamental frequency. A measuring probe 8 from the measurement system 1 is inserted in the power transmission path of the RF based excitation system 50 to measure the voltage and current signals transmitted through the RF transmission lines 4. The measuring probe 8 is a high power device comprising a voltage sensor 10 and a current sensor 12 for sensing the voltage and current signals, respectively. Voltage sensor 10 and current sensor 12 are connected to the center conductor of the RF transmission line 4, whereby the sensor housing itself becomes part of the outer conductor of the transmission line.

The probe 8 is connected to a measuring receiver 14 comprising RF connector input channels 10a and 12b for receiving the voltage and current signals from the voltage and current sensors 10, 12, respectively. The receiver 14 also comprises a digital interface (not shown) for uploading temperature readings and calibration data stored in the probe housing, so that individual impedance probes can be calibrated with calibration data stored within the probe housing.

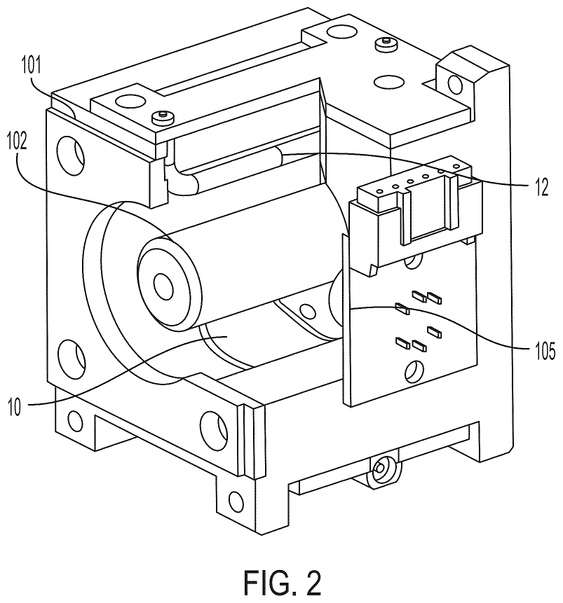

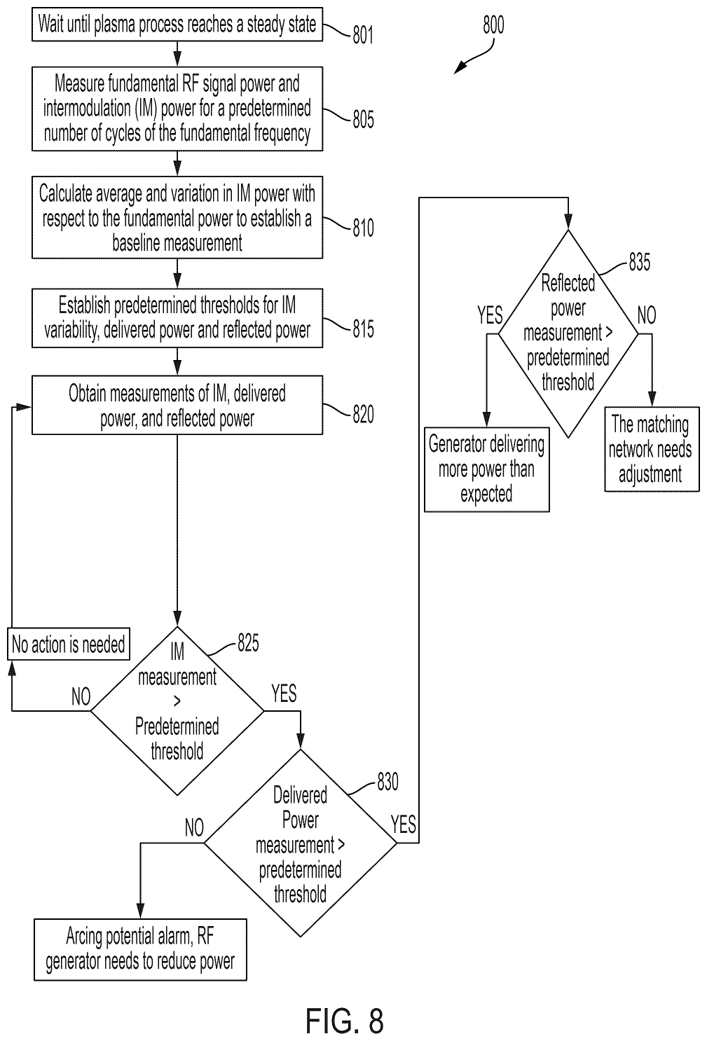

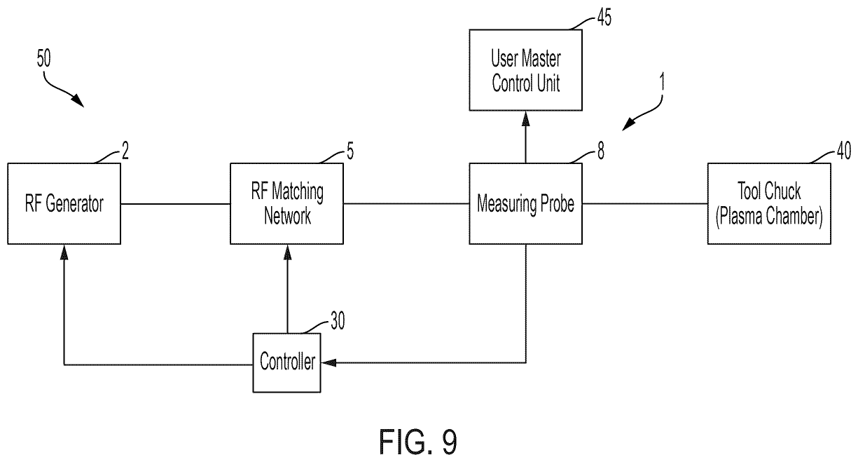

FIG. 1B is a block diagram illustrating the controller 30 of measurement system 1 of FIG. 1A. The controller 30 has a processor 31 for executing the instructions stored in memory 30. In some embodiments of controller 30, instructions for implementing the measuring receiver 14, digital conversion 20, signal processing 22 and/or D/A converter 26 are stored in memory 32 and executed by processor 31. Memory 32 may also contain instructions for controlling the RF generator, such as in response to the method 800 described below in FIG. 8 and shown in FIG. 9. Thus, in some embodiments of measurement system 1, controller 30 may be used to implement one or more of measuring receiver 14, digital conversion 20, signal processing 22, D/A converter 26, and RF generator control of RF based excitation system 50. Referring now to FIG. 2, the current sensor 12 of the measuring probe 8 comprises a single loop of rigid coaxial transmission line that is positioned parallel with the center conductor 102 of the probe 8 and associated transmission line 4. The outer conductor of the current sensor 12 is modified to act as a Faraday Shield, so that extraneous capacitive coupling is eliminated and only the mutually coupled RF current produces an output voltage. The voltage at one end of the current sensor loop 12 is connected to the measuring receiver interface in a manner known in the art to measure the current signals transmitted through the transmission line 4.

Referring again to FIG. 2, the voltage sensor 10 typically comprises a disk that is capacitively coupled to the center conductor 102 of the probe 8. The voltage sensor 10 is connected to the input of the transmission line, which in turn is connected to the measuring receiver interface to receive and measure the RF voltage signals from the transmission line 4.

In one exemplary embodiment of the invention, the cavity region between the probe housing 101 and the center conductor 102 may be filled with a dielectric material in order to raise the breakdown voltage so that the measuring probe 8 can withstand voltage levels in excess of 7500 volts peak. It is understood that the dimensions of the center conductor 102 and the housing 101 may be adjusted so that the characteristic impedance of the line section is approximately 50 ohms.

In order to maintain the precision of the measurement results provided by the probe sensors 10, 12, the temperature of the center conductor 102 and outer conductor/housing 101 are constantly monitored, and small adjustments to sensor calibration coefficients are made to correct for inevitable changes in sensor coupling caused by heating of the center conductor 102.

Each probe 8 is characterized by a calibration process that determines the exact current and voltage coupling coefficients and the phase angle between them over the operating frequency range of the device. During the calibration process, the temperature of the center conductor 102 and outer conductor/housing 101 are recorded. This calibration data or information is stored within the probe assembly in digital form in memory and is retrieved each time the probe 8 is attached to a measuring receiver 14. As a result, multiple measuring probes 8 can share a single measuring receiver 14 because the locally stored temperature readings and calibration data is loaded each time the probes and receivers are mated. In addition to calibrating the individual probes, the interconnecting transmission lines are also individually calibrated. The calibration data from the transmission line is stored within the transmission line assembly itself. In our exemplary embodiment, the transmission line assembly consists of two RF cables and a data cable. A digital memory chip (digital memory) is located inside the data cable connector, allowing calibration data from the transmission line assembly to be stored within the transmission line assembly itself. The measuring receiver is adapted to download calibration data from the transmission line and the probe housing via a digital interface. In this way, the calibration process of the present invention allows each component to be calibrated individually. This individual calibration process advantageously allows interchangeability of individual components in the field without the requirement of performing a total system re-calibration.

In operation, the temperature of the center conductor 102 is constantly monitored using an infrared thermometer 105, and the reading is then compared to the temperature of the outer conductor/housing 101. The resulting temperature difference is used to make adjustments to the voltage and current coupling coefficients due to the change in size and spacing of the center conductor 102 with respect to the outer conductor/housing 101. Simultaneously, the parasitic reactance's associated with the probe components may also be determined. The calibration process also adjusts the measured impedance information to account for the parasitic reactance of the probe.

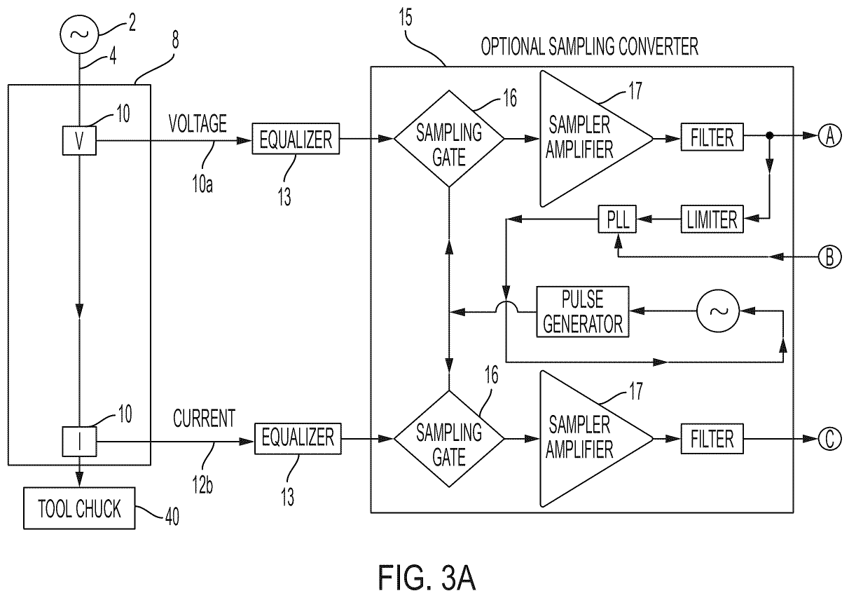

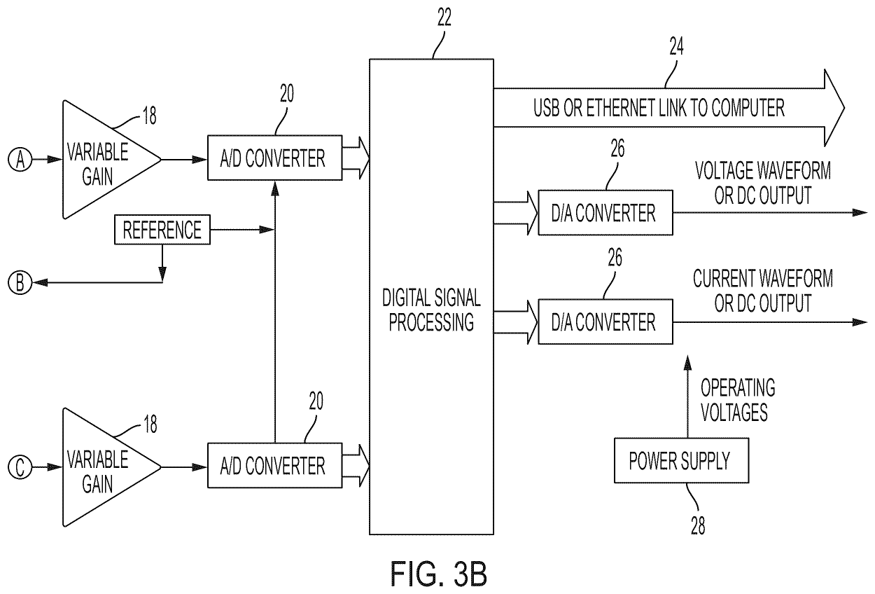

Turning now to FIGS. 3A, 3B, the voltage and current signals received from the voltage and current sensors 10, 12 are processed similarly. The voltage and current signals are isolated from each other by the respective voltage channel 10a and current channel 12b. Due to large fluctuations in signal levels associated with changes in the operating frequency, an active equalizer 13 is implemented between the voltage and current sensors 10, 12 in the form of a wide bandwidth operational amplifier with capacitive feedback. The equalizer 13 “integrates” the voltage and current signals to compensate for the “rate-of-change” response of the voltage and current sensors 10, 12. In one exemplary embodiment, the outputs of the equalizers are connected to a sampling-based frequency converter 15 to bring the signal under test to a fixed intermediate frequency (IF) before digital conversion. In another embodiment, the outputs of the equalizers 13 may be connected directly to variable gain stages 18 and A/D converters 20 for digital conversion.

As is described below, sampling of the RF signals may be performed by a sampler, which may be implemented by one or more of the sampling-based frequency converter 15, A/D converters 20, and/or digital signal processor 22. In some exemplary embodiments, the sampler may be a Nyquist sampling rate analog-to-digital converter 20 for sampling the RF signals. Further, in other embodiments, sampler may be a combination of a Nyquist sampling rate analog-to-digital converter 20 and a band-pass sampling analog-to-digital converter for sampling the RF signals.

As illustrated in FIG. 3A, an optional sampling-based frequency converter 15 may be used to convert the RF signals, intermodulation, triple beat, and harmonics thereof to much lower IF frequencies which are then compatible with bandwidth restrictions of existing high-resolution analog-to-digital (A/D) converter technology. In this embodiment, a pair of sampling gates 16 are part of a zero-order-hold circuit that captures a small sample of the RF signal and holds that value until the next sample is taken. The sampling gates are closed by a narrow pulse of about 300 picoseconds duration. During the instant that the sampling gate is closed, the RF signal voltage is impressed on a sampling capacitor. Sampler amplifiers 17 are employed to buffer the voltage on the sampling capacitor so that the level is maintained between samples. The bandwidth of the sampler is sufficiently wide so as not to significantly affect the phase of signals up to about 1000 MHz. Predictable delay related phase shift can be calibrated out in the digital signal processing circuits 22. Referring to FIGS. 3A, 3B, the IF signals are phase locked to the conversion cycle of the A/D converters 20 so that a plurality of samples can be taken for each cycle at the highest desired harmonic of the IF. In accordance with an exemplary embodiment of the invention, exactly four samples are taken for each cycle of the highest desired harmonic of the IF. In a preferred embodiment, the sampling rate is calculated so that the RF waveform reproduced at the IF frequency maintains the corresponding phase relationship between the fundamental signal frequency, intermodulation of the fundamental signal frequency, triple beat of the fundamental signal frequency and harmonics of the fundamental signal frequency, and preserves up to about fifteen orders of intermodulation, triple beat, and harmonics of the fundamental operating frequency.

One advantage of using a sampling-based frequency converter is that a local oscillator frequency shift from only about 1.95 to 2.1 MHz is needed to cover all of the typical plasma generator frequencies of 2, 13.56, 27.12, 60, and 162 MHz. Moreover, sampling-based frequency converters generally have the simplest architecture and highest bandwidth when compared to traditional mixer-based frequency converters.

However, because sampling down conversion translates all signals within the input RF bandwidth simultaneously, it may not be entirely appropriate for systems where multiple excitation signal frequencies are used. In the case of multiple excitation frequencies, Nyquist sampling may be advantageously used. It is also contemplated that the sampler may comprise a combination of a Nyquist sampling rate analog-to-digital converter and a band-pass sampling analog-to-digital converter for sampling and digitizing the RF voltage and current signals. It is known that Nyquist sampling acquires at least two samples per cycle of the highest frequency of interest. Once the signals have been digitized, digital signal processing circuitry 22 does additional signal processing including data capture management, mathematical transforms, filters, scaling, and creation of mathematically alterable analog outputs for external control systems. A port 24, such as, but not limited to, high-speed universal serial bus (USB) or Ethernet port, serves to connect the probe assembly to an external computer 21 for additional numerical and graphical analysis. A pair of digital-to-analog converters 26 may be employed to receive output from the digital signal processor 22 in order to reconstruct the original RF voltage and current waveforms. Power supply circuits 28 generate the necessary internal operating voltages from an external DC supply.

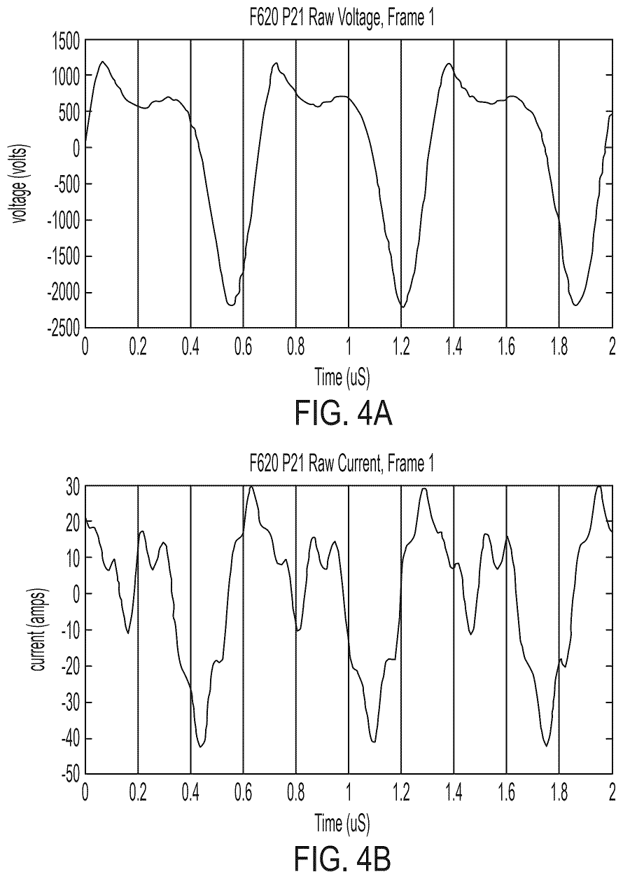

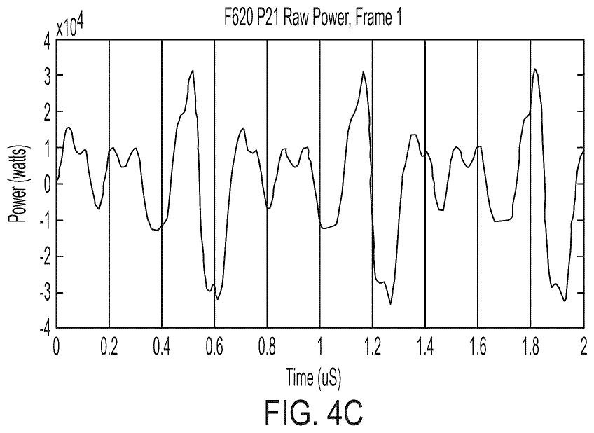

Referring now to FIGS. 4A, 4B, and 4C, there is shown exemplary waveform data generated in accordance with an embodiment of the present invention. FIG. 4A illustrates an exemplary raw voltage waveform, FIG. 4B illustrates an exemplary raw current waveform, and FIG. 4C illustrates an exemplary raw power waveform. In accordance with the present invention, Fourier transforms are used to separate the fundamental frequency, intermodulation, triple beat and harmonic components of the voltage and current signals so that digital signal processing algorithms can be applied to correct the amplitude and phase of individual frequency components. This process removes imperfections in the coupling response of the probe sensors and removes parasitic reactance associated with probe construction. Individual frequency components may then be recombined in the proper phase relationships so as to recreate the original voltage and current waveforms. The output results of the digital signal processing section comprise voltage, current, phase angle, power and impedance at each frequency component, along with waveform data.

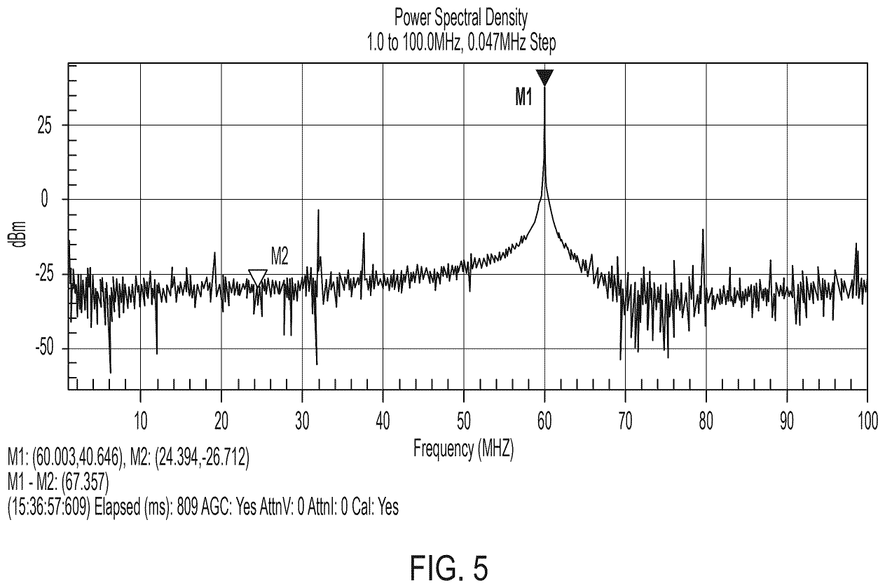

Referring now to FIG. 5, there is shown exemplary waveform data generated in accordance with an embodiment of the present invention. The data can be presented in a spectral mode to give an overview of the spectral components in each frequency band. In this view described as a spectral sweep mode with a start and stop frequency displaying the amplitude of each frequency. As shown in the figure a single frequency at 60 MHz.

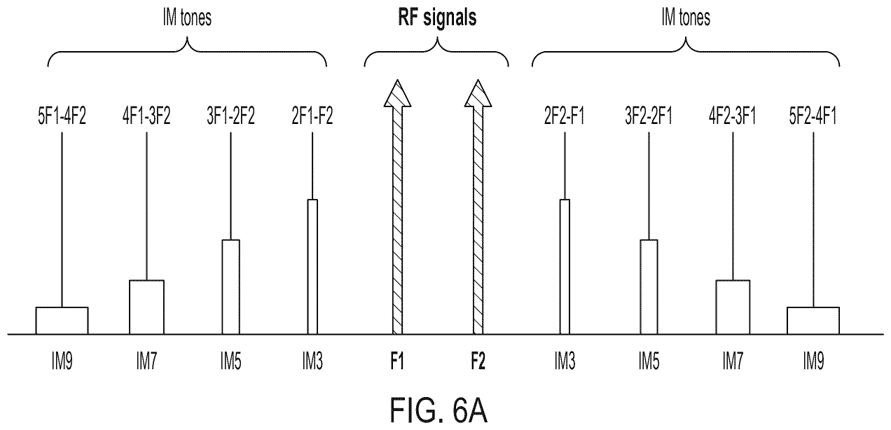

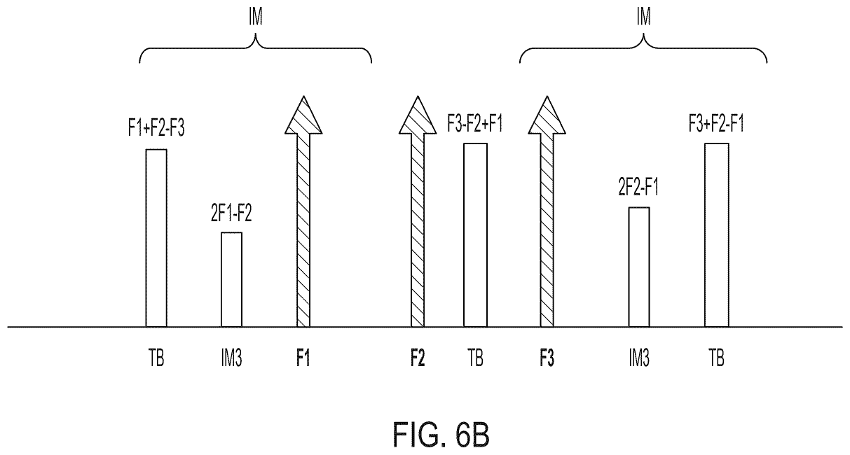

Turning to FIG. 6A, in some exemplary embodiments, the RF power source 2, such as an RF generator, may output two RF signals to generate plasma. The nonlinear nature of the plasma will generate intermodulation products (IM) based on the standard formulas for the two tone, which is, N*f1+/−M*f2, where N and M are positive integers that represent coefficients of the device, f1 is the first RF generator signal and f2 is the second RF generator signal. Further, IM3, IM5, IM7, and IM9 are the third, fifth, seventh, and ninth order intermodulation.

In some exemplary embodiments the RF power source 2 may output three RF signals to generate plasma. The nonlinear nature of plasma will generate intermodulation products based on the standard formulas for the 3 tone, which is, N*f1+/−M*f2+/−L*f3, where f1 is the first RF generator signal, f2 is the second RF generator signal, f3 is the third RF generator signal, and N, M, and L are positive integers that represent coefficients of the device. The device may include, but is not limited to, one or more of the power source 2 (RF generator), transmission lines 4, and tool chuck 40 (semiconductor plasma reactor). IM3 are third order intermodulation and TB are triple beat. Those IM signals from the three RF signals are called triple beat and are typically 6 dB stronger than their equivalent IM signals as shown in FIG. 6B.

As the plasma gets closer to arcing conditions the material changes and becomes more nonlinear and as result, the amplitude of the IM or the TB will increase. Therefore, it is contemplated that in some embodiments of the invention, the measurement system 1 will set an alarm once the amplitude of one or both of the IM or TB exceeds a predetermined amplitude threshold (predetermined threshold). In some embodiments, the measurement system 1 may send the alarm output to the power source 2, thereby permitting the power source 2 with sufficient warning to reduce power and avoid (inhibit) an arcing condition. The predetermined amplitude threshold (predetermined threshold) for the alert may be variable and user defined, such as based on the chamber conditions. In some exemplary embodiments, the predetermined amplitude threshold (predetermined threshold) may be 3 dB. In other exemplary embodiments, the predetermined amplitude threshold (predetermined threshold) may be about double the nominal IM value and TB value for the power output of the power source 2 for the chamber conditions. In other exemplary embodiments, the predetermined amplitude threshold (predetermined threshold) may be a value that a person having ordinary skill in the art finds suitable to avoid (inhibit) an arcing condition within the chamber. It is understood that in some embodiments this predetermined amplitude threshold (predetermined threshold) may be one or more of a predetermined IM threshold, predetermined delivered power threshold, and/or predetermined reflected power threshold, such as those described below.

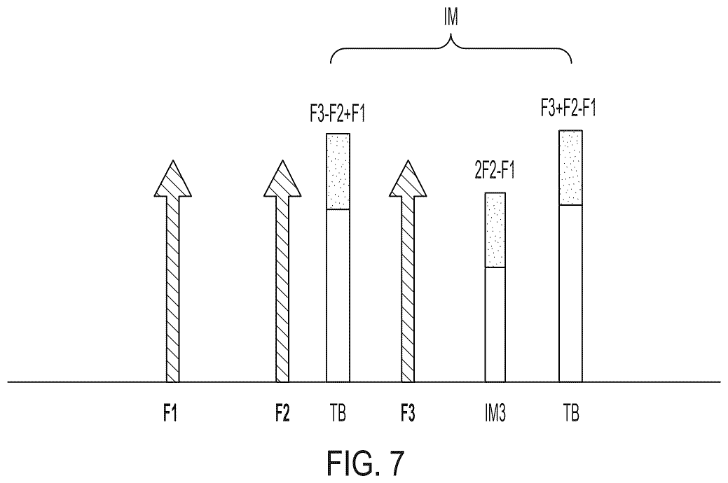

FIG. 7 shows the increase of the amplitude of IM3 and TB pre-arcing conditions, such as when compared to FIG. 6B. The stippled upper portions of IM3 and TB in FIG. 7 show the increase in signal amplitudes of TB and IM3. The TB and IM3 signal amplitudes are increased due to higher non-linearity indicating that the plasma in the chamber is close to arcing conditions.

Turning now to FIG. 8, there is illustrated a flow chart of method for detecting the conditions that arise prior to arcing. The method also identifies actions to be taken to rectify the conditions to prevent the arcing from taking place. In some embodiments, these identified actions to rectify the conditions may be performed programmatically by the user master control unit 45. In other embodiments, prompts to perform the identified actions may be sent to or displayed to a user, such as using the display 23 and/or master control unit 45, at which the user may then perform the actions. By detecting a condition that precedes arcing, it is possible to take preventative action, thereby avoiding wafer damage and loss of revenue associated with arcing.

The method can be used during any steady-state portion of the plasma process, for example, when applied RF and/or bias power is constant and when chamber pressure, temperature, and gas mixture are stable. Under these conditions, changes to intermodulation products are unexpected, that is, unrelated to planned process changes, and therefore can be used to detect the conditions leading up to arcing.

The method begins with establishing a baseline measurement of fundamental RF power and IM3 power. This may be accomplished by sampling a number of measurements and calculating the average value and standard deviation of fundamental and IM3. Thresholds are established based on the amount of typical variation in the IM3 power with respect to the fundamental power. The method continues by monitoring the IM3 power and looking for a noticeable increase in IM3 power, such as 2×the threshold that was established earlier. If such an increase is detected, the method continues by evaluating the fundamental RF power to see if a similar increase in power is measured. If an increase in fundamental RF power accompanies the increase in IM3 power, then the method continues by determining if the unexpected increase in fundamental RF power is due to a change in the RF generator or a change in the matching network. This information can be used to troubleshoot issues with the RF delivery system. If, however, no such increase in RF power is detected in the fundamental, but only in the IM3, then an alarm can be raised that a potential arcing condition exists. When this alarm is raised, the control system can either reduce the RF power, thereby preventing arcing from occurring or halt the process entirely until maintenance can be performed.

Stated alternatively, in method 800, the measurement system 1 waits until the plasma process of RF excitation system 50 reaches a steady state in 801. Once steady state has been reached, the method proceeds to 805, where the measurement system 1 measures the fundamental frequency RF signal power (fundamental frequency power) and IM power for a predetermined number of cycles of the fundamental frequency and stores in memory 32. The measurement system 1, may make the measurements using the measurement receiver 14, and/or probe(s) 8 containing voltage sensor 10 and/or current sensor 12. The IM power may be one or more of IM3, IM5, IM7, IM9, and/or TB. The predetermined number of cycles may be any number of cycles deemed suitable by a person having ordinary skill in the art. In an exemplary embodiment, IM may be IM3 and the predetermined number of cycles may be 5. In other exemplary embodiments, IM may be IM3 and/or TB, and the predetermined number of cycles may be a value between 1 and 10.

Following the measurements in 805, the averages and variations in IM power are calculated with respect to the fundamental frequency power to establish a baseline measurement in 810 using processor 31 based on the measurements stored in memory 32 acquired during 805. In an exemplary embodiment, the average value and standard deviation of the power of the fundamental and IM are calculated, as well as in some embodiments the average value and standard deviation of the IM power with respect to the fundamental frequency. The fundamental frequency power may be power in the forward (delivered power) as well as the reflected directions (reflected power). These calculations are then stored in memory 32.

In 815, predetermined thresholds are established (set) based on the average value and standard deviation calculated in 810. Predetermined thresholds may be established based on the amount of typical variation in the IM power with respect to the fundamental frequency power. For example, the predetermined thresholds may be a predetermined multiple of the average value and standard deviation calculated in 810, such as a multiple between 2 and 5. In an exemplary embodiment, the predetermined IM threshold may by one or both of twice the average value and standard deviation calculated for the fundamental frequency power and IM power calculated in 810.

Further, predetermined thresholds may also be established for the delivered power and reflected power in 815. Such predetermined delivered power threshold and predetermined reflected power threshold may be multiples of the average values of the delivered and reflected power, such as a multiple between 2 and 5. In an exemplary embodiment, the predetermined delivered power and predetermined reflected power thresholds may be twice the average value calculated for the delivered power and reflected power of the fundamental frequency power in 810.

These predetermined thresholds may be established using processor 31 and stored in memory 35.

After the predetermined thresholds are established in 815, measurements of the IM, delivered power, and reflected power are obtained in 820, such as by using the measurement receiver 14, and/or probe(s) 8 containing voltage sensor 10 and/or current sensor 12 and stored in memory 32. After the measurements are taken in 820 and stored in memory 32, the measurements in 820 for the IM power are compared to the predetermined threshold in 825 from memory 32 using controller 30 to ascertain if the IM power measurement exceeds the predetermined IM power threshold. If the IM power measurement does not exceed the predetermined IM power threshold, then the method returns to 820 where additional measurements are taken and stored in memory 32, such as using the measurement receiver 14, and/or probe(s) 8 containing voltage sensor 10 and/or current sensor 12. However, if the IM power measurement exceeds the predetermined IM power threshold, then the method moves to 830, where the delivered power measurement from 820 is compared to the predetermined delivered power threshold. If the delivered power measurement does not exceed the predetermined delivered power threshold, then arcing potential exists. In some embodiments, one or more of the following may take place: an arcing potential alarm is set, such as on the user master control unit 45, informing the user of the potential arcing condition and permitting the user to reduce RF generator power; and/or reduce the RF generator power, such as by using controller 30 and/or RF generator control 35, thereby mitigating the potential arcing condition.

In 830, if the delivered power measurement of the fundamental frequency power measurement does exceed the predetermined delivered power threshold of the predetermined fundamental frequency threshold, then the reflected power measurement is compared to the predetermined reflected power threshold of the predetermined fundamental frequency threshold from memory 32 using controller 30 in 835. If the reflected power measurement of the fundamental frequency power exceeds the predetermined reflected power threshold, then the generator is delivering more power than expected. In some embodiments, an excess generator power delivery alarm may be set using controller 30, such as on the user master control unit 45, informing the user that the generator is delivering more power than expected. If the reflected power measurement does not exceed the predetermined reflected power threshold, then the matching network needs adjusted. In some embodiments, a matching network adjustment alarm may be set using the controller 30, such as on the user master control unit 45, informing the user that the matching network needs adjustment.

In an exemplary embodiment, method 800 may be stored in memory 32 and executed by processor 31 of controller 30 in measurement system 1.

Although descriptions above may be described with reference to third-order intermodulation IM3, the same methods may be equally applied to the fifth order (IM5) or higher order intermodulation, or triple-beat in the case of three RF generator signals or a combination of intermodulation and triple beat. The methods may also be applied to a combination of fundamental, intermodulation, triple beat, and harmonic frequencies that can be user-defined based on specific scenarios.

FIG. 9 is a basic block diagram of a measurement system 1 that can be used to monitor fundamental RF power and intermodulation power generated by an RF excitation system 50 so as to determine if the potential for arcing exists and provide feedback to the controller (control system) 30 of the measurement system 1 to prevent arcing from occurring in the RF excitation system 50. The RF excitation system 50 may include an RF generator 2 that can output two or more frequencies. Alternatively, the system may include two or more RF generators 2 that output one frequency each. The multiple frequencies are combined in the matching network 5 (or matching networks) to deliver RF power into the tool chuck (plasma chamber) 40 with the best possible efficiency. In an exemplary embodiment, the measuring probe(s) 8 of the RF measurement system 1 is installed between the matching network 5 and the plasma chamber 40 to measure the RF power in each of the fundamental frequencies as well as some or all of the harmonics and intermodulation products in order to monitor the performance of the system and the risk of an arcing condition within plasma chamber 40. This information is conveyed directly from the measurement system 1, such as by the controller 30, to one or more of the RF generator(s) 2, matching network(s) 5, or user master control unit 45 of the RF excitation system 50 so as to intervene and prevent (mitigate) arcing from occurring.

When multiple probes are used, the input and output impedances and insertion loss can also be determined easily. Once the two-port impedance parameters are determined, all other two-port parameters can be calculated. For example, the impedance parameters can be converted to admittance or scattering parameters.

According to one aspect of the present invention, the probes (and the measurement system 1) use the principle of error reduction by cross-correlation. It is widely understood that the uncertainty of a measurement can be reduced by the square root of N, where N is the number of uncorrelated measurements of the same information. By using N uncorrelated measurements, the uncertainty of the RF power can be reduced.

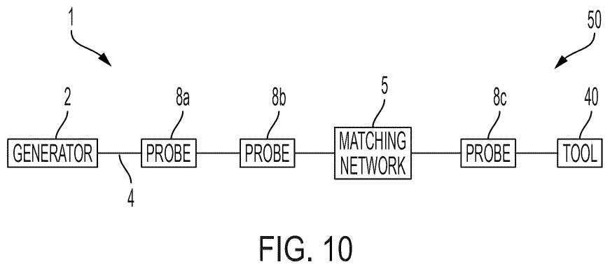

Turning now to FIG. 10, there is illustrated a method for analyzing power flow in an RF based excitation system 50, wherein two or more measuring probes 8a, 8b, 8c of RF power measurement system 1 are inserted at different points in the RF power transmission line 4 so as to reveal information about power flow parameters in the RF excitation system 50. For example, measuring probe 8a may be inserted between the generator 2 and transmission line 4, whereas measuring probe 8b may be inserted between the transmission line and matching network 5, and probe 8c may be inserted between the matching network 5 and the tool chuck 40. The outputs from the networked probes can then be combined to reveal information about the impedance match and insertion loss of the components in the RF excitation system.

Measurements from the multiple probes are made simultaneously at the fundamental, intermodulation, triple beat and harmonically related signal frequencies. The networked probes are then interrogated to recover instantaneous voltage, current, and phase information representing power flow and impedance levels at different points in the power application path. In this way, the characteristics of transmission lines 4, matching devices 5, connectors, and reactor plasma itself can then be quantified, for example, by calculating two-port impedance, admittance, transmission, and/or scattering parameters associated with pairs of probes. The calculations reveal the characteristics of each component at the fundamental excitation frequency and each of the intermodulation, triple beat and harmonics simultaneously. For example, two-port measurements from the probes 8b, 8c positioned before and after the matching network, respectively, can be used to determine input or output impedance (admittance), insertion loss, internal dissipation, and power transmission efficiency at the fundamental or the intermodulation, triple beat and harmonic frequencies of the RF signal. Measurements from probe 8c positioned between the matching network 5 and the tool chuck 40 can be used to reconstruct the RF voltage and current waveforms to observe the effect of plasma non-linearity on the RF signals.

The exemplary methods discussed above provide critical information about the fundamental and harmonic amplitude and phase relationships of the RF excitation signals. This information can then be monitored to determine faults and improper operation in any of the functional blocks during normal tool operation. The probes may be checked periodically in a maintenance mode, and the measurement data may be analyzed to identify opportunities for process improvement. In a preferred embodiment, the measuring probes are constructed to isolate the voltage and current signals and maintain sufficient RF bandwidth to preserve up to at least fifteen intermodulation, triple beat, and harmonics of the highest test (i.e. excitation) signal frequency, although it is contemplated that more or less intermodulation, triple beat, and harmonics of the test signal could be preserved without departing from the scope of the present invention.

As discussed above, a single measuring receiver may be employed to retrieve data from several probes, and the data from the several probes may be fed to an external computer for post processing. Multiple measuring receivers may be connected to each of the impedance probes individually, thereby allowing for “real time” processing of system data. The bulk of signal processing is done using an external computer, and results are presented and displayed by display 23 in a flexible user-controlled format.

While this invention has been described with respect to particular embodiments thereof, it is apparent that numerous other forms and modifications of this invention will be obvious to those skilled in the art. The appended claims and this invention generally should be construed to cover all such obvious forms and modifications which are within the true spirit and scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as critical, required, or essential features or elements of any or all the claims. As used herein, the terms “comprises, “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. Further, no element described herein is required for the practice of the invention unless expressly described as “essential” or “critical.” While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes and combinations can be made without departing from the spirit and scope of this invention. Combinations of the above embodiments and other embodiments will be apparent to those of skill in the art upon studying the above description and are intended to be embraced therein. Therefore, the scope of the present invention is defined by the appended claims, and all devices, processes, and methods that come within the meaning of the claims, either literally or by equivalence, are intended to be embraced therein.

What is claimed is:

1. A system for analyzing power flow in a radio frequency (RF) power transmission line, comprising:
a measuring probe having a voltage sensor and a current sensor for sensing RF voltage and current signals from said transmission line, said RF voltage and current signals having waveforms;
a measuring receiver connected to said voltage and current sensors for receiving said RF signals;
a sampler for directly converting said RF signals to digital signals, said digital signals comprising amplitude and phase information representing a fundamental frequency of said RF signals and a predetermined number of intermodulation (IM), triple beat (TB), and harmonic frequencies.

2. The system of claim 1 further comprising:
a digital signal processor for characterizing said amplitude and phase information so as to analyze power flow parameters and to reveal amplitude and phase angle relationships between said fundamental, intermodulation, triple beat, and harmonic frequencies;
wherein said digital signal processor reconstructs said RF voltage and current waveforms by recombining said harmonic frequencies in the proper phase relationships using said information about phase angle relationships between said fundamental, intermodulation, triple beat, and harmonic frequencies.

3. The system of claim 1, wherein said system generates an alarm when said amplitude of at least one of said intermodulation or triple beat frequencies exceed a predetermined threshold.

4. The system of claim 3, wherein said predetermined threshold is:
about 3 dB,
about double a nominal IM value for a power output of a power source for conditions of a chamber,
about double a nominal TB value for said power output of said power source for conditions of said chamber, and/or
a value that inhibits an arcing condition within said chamber.

5. The system of claim 3, wherein said predetermined threshold is a predetermined IM threshold, a predetermined delivered power threshold, and/or a predetermined reflected power threshold.

6. The system of claim 1, further comprising a digital-to-analog converter for reconstructing said RF signals.

7. The system of claim 1, wherein said probe and said transmission line comprise memory for storing calibration data from said probe and said transmission line, respectively.

8. The system of claim 1, wherein the system takes at least three uncorrelated individual measurements of said RF signals using cross-correlation for reduction of uncertainty, wherein said individual measurements of said RF signals are averaged together, thereby producing an aggregate average measurement of said RF signals and providing to a user a more accurate representation of said fundamental frequency of said RF signals and said predetermined number of intermodulation or triple beat and harmonic frequencies.

9. The system of claim 7, wherein said measuring receiver comprises a digital interface for receiving said calibration data from said probe and said transmission line.

10. The system of claim 9, further comprising a computer connected to said digital signal processor for additional numerical and graphical processing of said digital signals.

11. The system of claim 10, further comprising an equalizer to compensate for fluctuations in said RF voltage and current signals.

12. The system of claim 1, wherein said sampler comprises a band-pass sampling analog-to-digital converter for sampling said RF signals.

13. The system of claim 1, wherein said sampler comprises a Nyquist sampling rate analog-to-digital converter for sampling said RF signals.

14. The system of claim 1, wherein said sampler comprises a combination of a Nyquist sampling rate analog-to-digital converter and a band-pass sampling analog-to-digital converter for sampling said RF signals.

15. The system of claim 1, wherein said predetermined number of intermodulation, triple beat, and harmonics includes up to about fifteen orders of said fundamental frequency.

16. The system of claim 2, wherein said power flow parameters comprise input impedance, insertion loss, internal dissipation, plasma non-linearity, power flow efficiency, scattering, and combinations thereof.

17. A method of analyzing power flow in an RF transmission line, comprising the steps of:
connecting at least one measuring probe to said RF transmission line.
receiving RF voltage and current signals from said RF transmission line via said at least one measuring probe, said RF voltage and current signals having waveforms;
converting said RF signals to corresponding digital signals, said digital signals comprising amplitude and phase information representing a fundamental frequency of said RF signals and a predetermined number of intermodulation, triple beat, and harmonic frequencies.

18. The method of claim 17, wherein said predetermined number of intermodulation, triple beat, and harmonics includes up to about fifteen orders of said fundamental frequency.

19. The method of claim 17 further comprising:
processing said digital signals so as to analyze power flow parameters and to reveal amplitude and phase angle relationships between said fundamental, intermodulation, triple beat, and harmonic frequencies;
wherein said information about phase angle relationships between said fundamental, intermodulation, triple beat, and harmonic frequencies permits the recombining of said harmonic frequencies in the proper phase relationships so as to reconstruct said RF voltage and current waveforms.

20. The method of claim 19, wherein said power flow parameters comprise input impedance, insertion loss, internal dissipation, plasma non-linearity, power flow efficiency, scattering, and combinations thereof.

21. The method of claim 17, wherein said method further comprises generating an alarm when said amplitude of at least one of said intermodulation or triple beat frequencies exceed a predetermined threshold.

22. The method of claim 21, wherein said predetermined threshold is:
about 3 dB,
about double a nominal IM value for a power output of a power source for conditions of a chamber,
about double a nominal TB value for said power output of said power source for conditions of said chamber, and/or
a value that inhibits an arcing condition within said chamber.

23. The method of claim 21, wherein said predetermined threshold is a predetermined IM threshold, a predetermined delivered power threshold, and/or a predetermined reflected power threshold.

24. The method of claim 17, further comprising the steps of: converting said digital signals to analog signals so as to reconstruct said RF signals; and transmitting said digital signals to an external computer for additional numerical and graphical processing.

25. The method of claim 24, further comprising the steps of storing calibration data from said at least one measuring probe and said transmission line and downloading said calibration data to a measuring receiver.

26. The method of claim 25, further comprising the steps of interchanging said at least one measuring probe and/or said transmission line, and downloading updated calibration data from said interchanged at least one measuring probe and/or transmission line to said measuring receiver.

27. The method of claim 17, wherein the method further comprises taking at least three uncorrelated individual measurements of said RF signals using cross-correlation for reduction of uncertainty, wherein said individual measurements of said RF signals are averaged together, thereby producing an aggregate average measurement of said RF signals and providing to a user a more accurate representation of said fundamental frequency of said RF signals and said predetermined number of intermodulation or triple beat and harmonic frequencies.

28. The method of claim 26, further comprising the step of displaying results of said additional numerical and graphical processing steps in a user controlled format.

29. The method of claim 27, further comprising the steps of: connecting an RF power source and a tool chuck to said RF transmission line; connecting a matching network to said RF transmission line between said power source and said tool chuck; connecting at least one of said at least one measuring probe between said power source and said matching network, and connecting another one of said at least one measuring probe between said matching network and said tool chuck.

30. The method of claim 28, wherein said receiving said RF voltage and current signals is performed by taking at least two samples for each cycle at a highest said predetermined harmonics of said fundamental frequency.

31. A system for analyzing power flow in a radio frequency (RF) power transmission line, comprising:
a measuring probe for sensing RF voltage and current signals on said transmission line, said signals having a waveform;
a processor and a memory communicatively connected to said processor, the memory storing instructions that, when executed by said processor, cause said processor to:
measure on said transmission line a fundamental frequency RF signal power and an intermodulation (IM) power for a predetermined number of cycles of the fundamental frequency at a steady state using said measuring probe;
calculate baseline measurements using said measurements of said fundamental frequency RF signal power and said IM power, said baseline measurements comprising one or more of an average and a variation in said IM power with respect to said fundamental frequency power.
establish predetermined thresholds for said fundamental frequency power and said IM power based on said calculated baseline measurements;
obtain measurements of said fundamental frequency power and said IM power on said transmission line, and compare said measured fundamental frequency power and said IM power to said predetermined threshold for said fundamental frequency power and said predetermined threshold for said IM power to detect a presence of a potential arcing condition; and
set an alarm and/or mitigate said potential arcing condition, when said potential arcing condition is detected.

32. The system of claim 31, the memory storing instructions that, when executed by the processor, cause the processor to:
set an arcing potential alarm and/or reduce power of an RF generator, when said IM power measurement exceeds said predetermined IM power threshold, and a delivered power measurement of said measured fundamental frequency power does not exceed a predetermined delivered power threshold of said predetermined fundamental frequency power threshold.

33. The system of claim 31, the memory storing instructions that, when executed by the processor, cause the processor to:
set an excess power delivery alarm, when:
said IM power measurement exceeds said predetermined IM power threshold;
a delivered power measurement of said measured fundamental frequency power exceeds a predetermined delivered power threshold of said predetermined fundamental frequency power threshold; and
a delivered power measurement of said measured fundamental frequency power exceeds a predetermined delivered power threshold of said predetermined fundamental frequency power threshold.

34. The system of claim 31, the memory storing instructions that, when executed by the processor, cause the processor to:
set a matching network adjustment alarm, when:
said IM power measurement exceeds said predetermined IM power threshold;
a delivered power measurement of said measured fundamental frequency power exceeds a predetermined delivered power threshold of said predetermined fundamental frequency power threshold; and
a reflected power measurement of said measured fundamental frequency power exceeds a predetermined reflected power threshold of said predetermined fundamental frequency power threshold.

35. The system of claim 31, wherein IM power is one or more of IM3, IM5, IM7, IM9, and/or TB.

36. The system of claim 31, wherein said predetermined number of cycles may be a value between 1 and 10.

37. The system of claim 31, wherein said predetermined fundamental frequency power threshold is a multiple between 2 and 5 of the average fundamental frequency power at steady state, and/or said IM power threshold is a multiple between 2 and 5 of the average value and/or standard deviation in the IM power with respect to the fundamental frequency power at steady state.

38. A method for analyzing power flow in a radio frequency (RF) power transmission line, comprising:
providing a measuring probe for sensing RF voltage and current signals on said transmission line, said signals having a waveform;
measuring on said transmission line a fundamental frequency RF signal power and an intermodulation (IM) power for a predetermined number of cycles of the fundamental frequency at a steady state using said measuring probe;
calculating baseline measurements using said measurements of said fundamental frequency RF signal power and said IM power, said baseline measurements comprising one or more of an average and a variation in said IM power with respect to said fundamental frequency power.
establishing predetermined thresholds for said fundamental frequency power and said IM power based on said calculated baseline measurements;
obtaining measurements of said fundamental frequency power and said IM power on said transmission line, and comparing said measured fundamental frequency power and said IM power to said predetermined threshold for said fundamental frequency power and said predetermined threshold for said IM power to detect a presence of a potential arcing condition; and
setting an alarm and/or mitigate said potential arcing condition, when said potential arcing condition is detected.

39. The method of claim 38, the method further comprising, setting an arcing potential alarm and/or reduce power of an RF generator, when said IM power measurement exceeds said predetermined IM power threshold, and a delivered power measurement of said measured fundamental frequency power does not exceed a predetermined delivered power threshold of said predetermined fundamental frequency power threshold.

40. The method of claim 38, the method further comprising, setting an excess power delivery alarm, when:
said IM power measurement exceeds said predetermined IM power threshold;
a delivered power measurement of said measured fundamental frequency power exceeds a predetermined delivered power threshold of said predetermined fundamental frequency power threshold; and
a delivered power measurement of said measured fundamental frequency power exceeds a predetermined delivered power threshold of said predetermined fundamental frequency power threshold.

41. The method of claim 38, the method further comprising, setting a matching network adjustment alarm, when:
said IM power measurement exceeds said predetermined IM power threshold;
a delivered power measurement of said measured fundamental frequency power exceeds a predetermined delivered power threshold of said predetermined fundamental frequency power threshold; and
a reflected power measurement of said measured fundamental frequency power exceeds a predetermined reflected power threshold of said predetermined fundamental frequency power threshold.

42. The method of claim 38, wherein IM power is one or more of IM3, IM5, IM7, IM9, and/or TB.

43. The system of claim 38, wherein said predetermined number of cycles may be a value between 1 and 10.

44. The system of claim 38, wherein said predetermined fundamental frequency power threshold is a multiple between 2 and 5 of the average fundamental frequency power at steady state, and/or said IM power threshold is a multiple between 2 and 5 of the average value and/or standard deviation in the IM power with respect to the fundamental frequency power at steady state.
